(19) United States
(12) Patent Application Publication
(10) Pub. No.: US 2026/0324015 A1
(43) Pub. Date: Oct. 15, 2026

(54) SUPER-JUNCTION TRANSISTOR WITH ORTHOGANAL SHIELD LAYER

(71) Applicant: SEMICONDUCTOR COMPONENTS INDUSTRIES, LLC, Scottsdale, AZ (US)

(72) Inventors: Jimmy Robert Hannes FRANCHI, Enköping (SE); Krister GUMAELIUS, Vaxholm (SE); Tanuj SAXENA, Chandler, AZ (US); Gary Horst LOECHELT, Tempe, AZ (US)

(73) Assignee: SEMICONDUCTOR COMPONENTS INDUSTRIES, LLC, Scottsdale, AZ (US)

(21) Appl. No.: 19/175,873

(22) Filed: Apr. 10, 2025

(51) Int. Cl. H10D 62/10; H10D 30/01; H10D 30/66; H10D 62/00; H10D 62/832

(52) U.S. Cl. CPC H10D 62/111; H10D 30/0297; H10D 30/668; H10D 62/054; H10D 62/8325

(57) ABSTRACT

A transistor is disclosed. The transistor includes a source region having a first conductivity type, a well region under the source region and having a second conductivity type, and a current-spreading layer under the well region and having the first conductivity type. The transistor includes a gate formed in a trench and disposed in a striped gate pattern. The transistor further includes a transition region having the first conductivity type and a shield region having the second conductivity type located under the current-spreading layer. The transition and shield regions alternatingly disposed in a striped transition-region pattern that is angularly offset from the striped gate pattern. The transistor also includes a super-junction region under the shield region and the transition region. The super-junction region includes an n-type pillar and a p-type pillar alternatingly disposed in a striped super-junction pattern that is angularly offset from the striped transition-region pattern.

### TECHNICAL FIELD

The disclosure relates generally to semiconductor devices, and particularly to techniques for improving area utilization of power transistors.

### BACKGROUND

Power electronics may be used to control the conversion and distribution of electric power. For example, switching power converters may be used to create a direct current (DC) voltage from an alternating current (AC) voltage by switching current through a magnetic element such as an inductor. Conversely, inverters can be used to convert a DC voltage to an AC voltage. In these and other forms of power electronics, power switches may be used to control the conversion and flow of power through the power-conversion system and to the electronic circuitry to be powered by the device.

Power switches utilized in such power-conversion systems may be required to handle high currents and to withstand large voltages. Inventors of embodiments of the present disclosure have recognized that optimizing certain performance parameters of power switches may come at the expense of worsening other performance parameters of power switches. For example, inventors of embodiments of the present disclosure have recognized that reducing the on-state resistance (RON) of a power transistor to reduce conduction losses may come at the expense of a reduced short-circuit withstand time (SCWT). As another example, inventors of embodiments of the present disclosure have also recognized that certain techniques for reducing the on-state resistance (RON) of a power transistor may come at the further expense of reducing the breakdown voltage (BV) of the power transistor. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a perspective view of a transistor in accordance with embodiments of the present disclosure.

FIG. 2A illustrates a cross-section view of a transistor in accordance with embodiments of the present disclosure.

FIG. 2B illustrates a cross-section view of a transistor in accordance with embodiments of the present disclosure.

FIG. 2C illustrates a top cross-section view of a transistor in accordance with embodiments of the present disclosure.

FIG. 2D illustrates a top cross-section view of a transistor in accordance with embodiments of the present disclosure.

FIG. 3A illustrates a perspective view of a transistor in accordance with embodiments of the present disclosure.

FIG. 3B illustrates a perspective view of a transistor in accordance with embodiments of the present disclosure.

FIG. 3C illustrates a perspective view of a transistor in accordance with embodiments of the present disclosure.

FIGS. 3D and 3E illustrate top views of link implant patterns in accordance with embodiments of the present disclosure.

FIG. 4 illustrates a top layout view of a transistor in accordance with embodiments of the present disclosure.

FIG. 5 illustrates a method for manufacturing a super-junction transistor in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other elements and connections.

Embodiments disclosed herein may include a transistor. The transistor may be a metal-oxide semiconductor field-effect transistor (MOSFET). In some embodiments, the transistor may be a silicon carbide transistor formed on a silicon carbide substrate. In other embodiments, the transistor may be implemented in silicon, gallium nitride, or any other suitable semiconductor material. As described in further detail below, the transistor may include a super-junction region, and may thus also be referred to as a super-junction transistor.

The transistor may include a source region having a first conductivity type, a well region located under the source region and having a second conductivity type, and a current-spreading layer located under the well region and having the first conductivity type. The transistor may also include a vertical gate formed in a trench extending through the source region, the well region, and the current-spreading layer. The vertical gate may be disposed in a striped pattern in a first direction of a first axis. The transistor may include a transition region located under the current-spreading layer and having the first conductivity type, and also include a shield region located under the current-spreading layer and having the second conductivity type. The transition region and the shield region may be disposed in an alternating fashion in a striped transition-region pattern angularly offset from the striped gate pattern. For example, the transition region and the shield region may be disposed in an alternating fashion in a striped transition-region pattern in a second direction of a second axis orthogonal to the first axis. The transistor may also include a super-junction region located under the shield region and the transition region. The super-junction region may include an n-type pillar and a p-type pillar. The n-type pillar and the p-type pillar may be disposed in an alternating fashion in a striped super-junction pattern angularly offset from the striped transition-region pattern. For example, the n-type pillar and the p-type pillar may be disposed in an alternating fashion in a striped super-junction pattern in the direction of the first axis orthogonal to the second axis. The transistor may also include an epitaxial region having the first conductivity type located under the super-junction region and above a drain contact layer.

In some embodiments, the transistor may be an n-channel MOSFET (“NMOS” or “NMOS transistor”). For example, the first conductivity type may be n-type, and each of the source region, the current-spreading layer, the transition region, and the epitaxial region, may be n-type doped regions. In such embodiments, the second conductivity type may be p-type, and both of the well region and shield region may be p-type doped regions.

Certain parameters of the transistor may depend on dimensions and doping of the various regions including the source region, the well region, the current-spreading layer, the transition region, the shield region, and the super-junction region. For example, the gate-pitch may affect how many fingers of the transistor may be implemented in parallel in a given area of the semiconductor substrate, and thereby may affect the on-resistance (RON) of the transistor. Further, the width of the transition region within the striped transition-region pattern, as well as the transition-region pitch of the striped transition-region pattern, may affect the saturation current of the transistor, and thereby the short-circuit withstand time of the transistor. In addition, the doping of the n-type pillar in the super-junction region, as well as the super-junction pitch, may affect the on-resistance (RON) and the breakdown voltage (BV) of the transistor. As described in further detail below, laying out various regions in striped patterns angularly offset from (for example orthogonal to) the patterns of neighboring regions above and/or below may allow the dimensions and doping of the various regions to be determined independent from each other. For example, by patterning the transition region and the shield region in a striped transition-region pattern orthogonal to (or otherwise angularly offset from) the striped gate pattern, the respective widths and pitch of the shield region and the transition region may be determined separately from the gate pitch of the striped gate pattern. The widths and pitch of the shield region and the transition region may thus be selected based on a target saturation current value, without being limited to the same pitch of the striped gate pattern. Further, by patterning the first pillar and the second pillar of the super-junction region in a striped pattern orthogonal to (or otherwise angularly offset from) the striped transition-region pattern, the pitch and the doping of the super-junction region may be determined separately from the striped transition-region pattern and separately from the striped gate pattern. Accordingly, the pitch of the super-junction region and the doping of the n-type pillar and the p-type pillar therein may be selected based on target on-resistance (RON) and breakdown voltage (BV) values, without being limited to the same pitch of the striped gate pattern or the striped transition-region pattern.

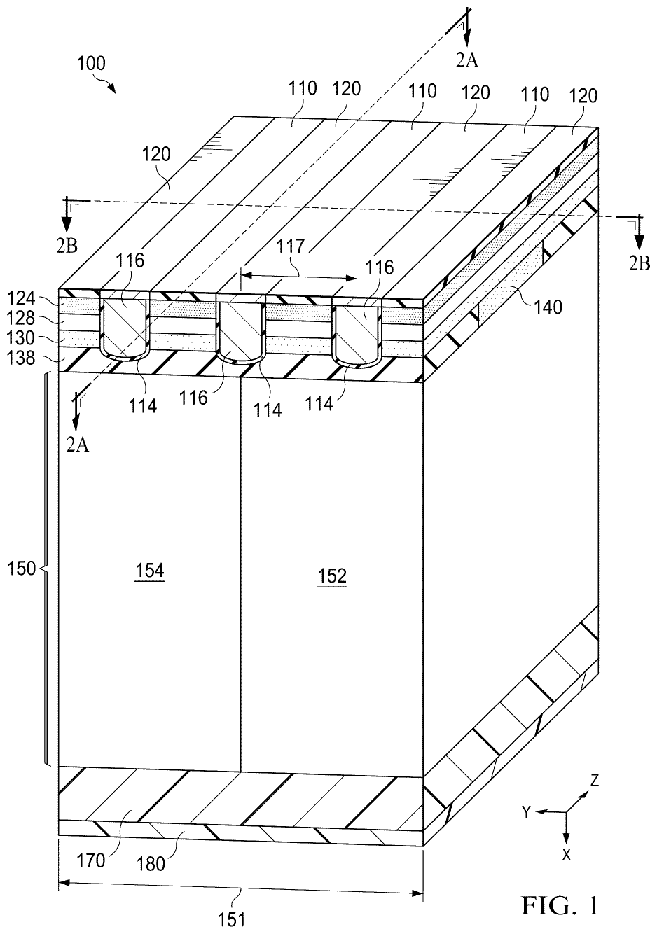

FIG. 1 illustrates a perspective view of transistor 100 in accordance with embodiments of the present disclosure. Specifically, FIG. 1 illustrates a perspective view of a portion of transistor 100 cut out from a semiconductor substrate. Although FIG. 1 illustrates portions of three fingers of transistor 100, transistor 100 may include further fingers (for example, 10, 100, 1000, or more) repeated in a similar pattern in further portions of the semiconductor substrate not shown in FIG. 1. In some embodiments, transistor 100 may be a silicon carbide transistor formed on a silicon carbide substrate. In other embodiments, transistor 100 may be implemented in silicon, gallium nitride, or any other suitable semiconductor material. As described in further detail below, transistor 100 may include a super-junction region, and may thus also be referred to as a super-junction transistor.

As shown in FIG. 1, transistor 100 may include source contact layer 120 located above source region 124. Source contact layer 120 may include, for example, a silicide that may improve the electrical conductivity of the contact between source region 124 and above metal layers (not shown in FIG. 1) coupled to the source terminal of transistor 100. Source region 124 may have a first conductivity type. For example, in embodiments where transistor 100 is an NMOS transistor, source region 124 may be a heavily doped n-type region. Transistor 100 may also include well region 128 located under source region 124. Well region 128 may have a second conductivity type. For example, in embodiments where transistor 100 is an NMOS transistor, well region 128 may be a doped p-type region. Transistor 100 may further include a current-spreading layer 130 located under well region 128. Current-spreading layer 130 may have the first conductivity type, similar to source region 124. For example, in embodiments where transistor 100 is an NMOS transistor, current-spreading layer 130 may be a doped n-type region.

Transistor 100 may also include gate 116 formed in a trench. Gate 116 may be a vertical gate whereby the trench extends downward (in the direction of the x-axis shown in FIG. 1) from an upper surface of the semiconductor substrate. In some embodiments, the trench may extend through source region 124 and well region 128. For example, as shown in FIG. 1, the trench may extend through source region 124 and well region 128, further through current-spreading layer 130, and into shield region 138. During manufacturing, the trench may be formed by an etch pattern at the upper surface of the semiconductor substrate. After the etch, gate oxide 114 may be grown or deposited along the sidewalls and bottom of the trench. Gate oxide 114 may include silicon dioxide, for example, or any other oxide suitable to form a gate dielectric. Gate 116 may subsequently be deposited to fill remaining area of the trench. In some embodiments, gate 116 may be formed by, for example, a heavily doped polysilicon. Gate 116 may also be formed by any other conductive material, such as a metal or metal alloy, suitable to form the physical gate of transistor 100. Interlayer dielectric 110 may be formed over gate 116. Interlayer dielectric 110 may electrically isolate gate 116 from source contact layer 120 and above metal layers coupled to the source terminal of transistor 100. Although not shown in FIG. 1, each instance of gate 116 may be coupled to above layers of gate metal by a contact through interlayer dielectric 110 for routing and coupling to the gate terminal of transistor 100 at a different location on the semiconductor die.

As shown in FIG. 1, gate 116 may be disposed in a striped gate pattern in a first direction of a first axis (for example the z axis shown in FIG. 1). Specifically, as shown in FIG. 1, stripes of gate 116 may extend length-wise in a direction of the z-axis, with the stripes repeating at a gate pitch 117 along the y-axis. Gate 116 may be separated from well region 128 by gate oxide 114. A vertical channel from source region 124, through well region 128, and to current-spreading layer 130, may thus be formed in well region 128 adjacent to gate oxide 114 and gate 116. As described in further detail below, during operation of transistor 100 in an on-state, current may flow from drain contact layer 180, through epitaxial region 170, through the n-type pillar 152 of super-junction region 150, through transition region 140, and through current-spreading layer 130, from where current may then flow to the source region 124 through the various channels opened in well region 128 by the application of a sufficient gate voltage to gate 116. The on-resistance of transistor 100 for a given semiconductor die area may depend in part on the number of instances of gate 116 that may be formed in the striped gate pattern. Thus, reducing the gate pitch 117 of the striped gate pattern may result in more instances of gate 116 for a given semiconductor area, and thus lower on-resistance.

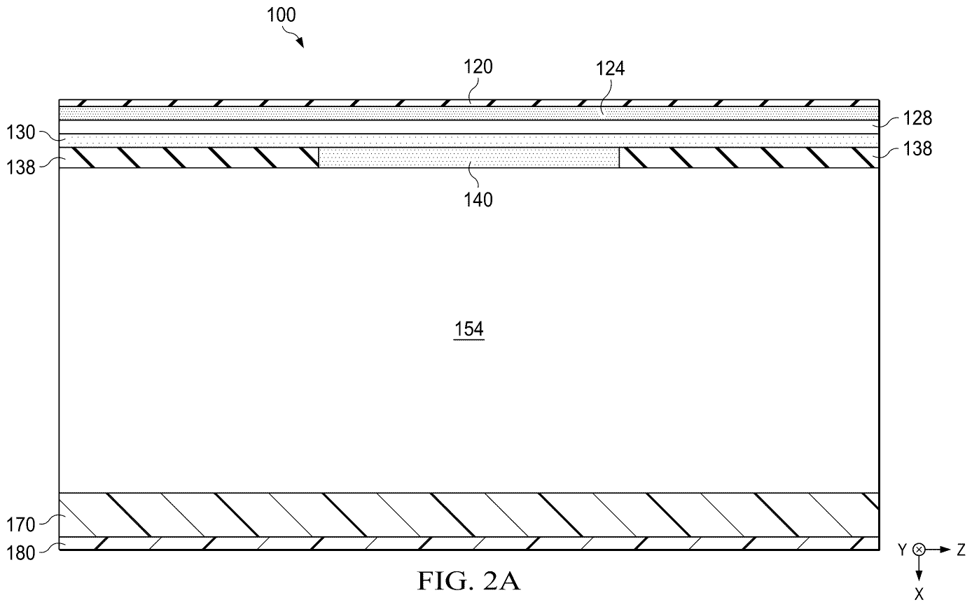

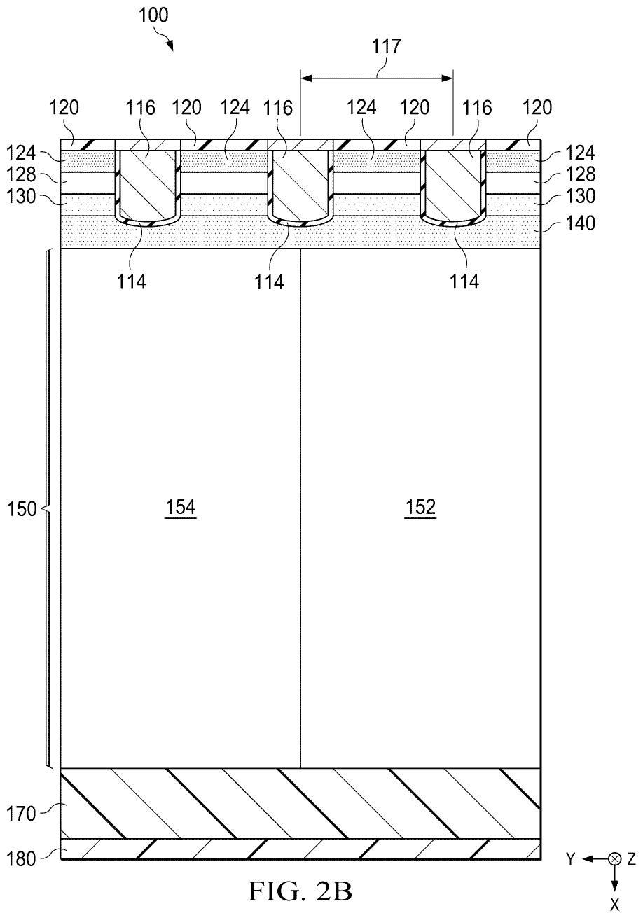

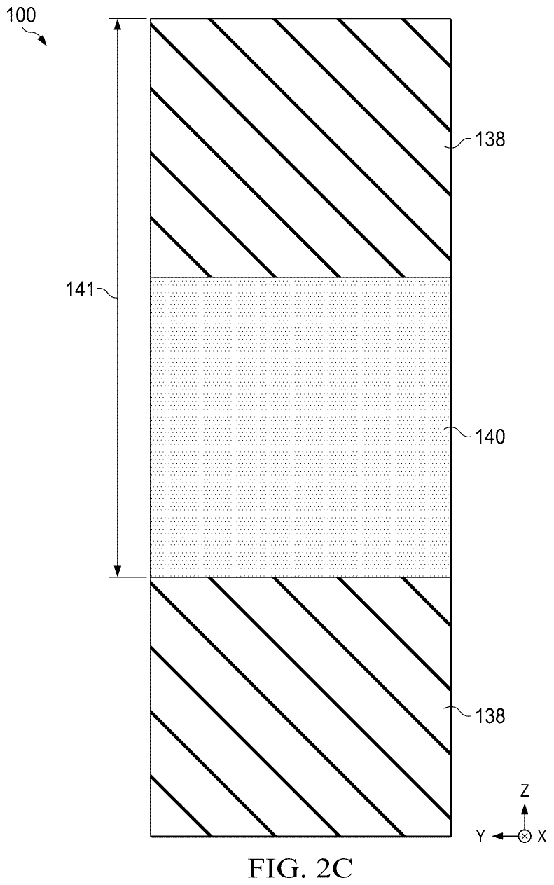

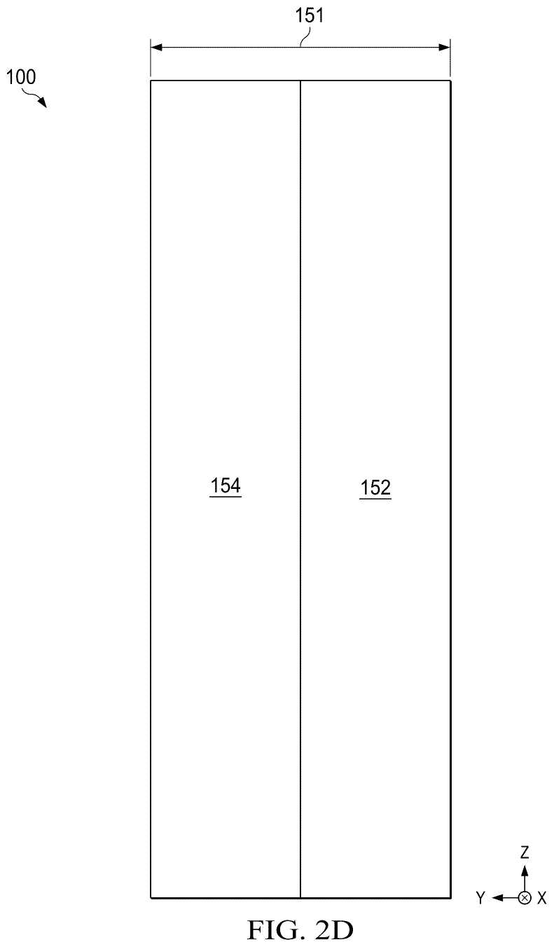

As shown in FIG. 1, transistor 100 may also include shield region 138 located under current-spreading layer 130. Shield region 138 may have the second conductivity type. For example, in embodiments where transistor 100 is an NMOS transistor, shield region 138 may be a doped p-type region. Shield region 138 may provide a shield protecting the above gate structures (including gate oxide 114) from electric fields in super-junction region 150 when a high voltage is applied across the drain and the source of transistor 100, thereby improving the breakdown voltage (BV) of transistor 100. Transistor 100 may further include transition region 140 located under current-spreading layer 130. Transition region 140 may have the first conductivity type. For example, in embodiments where transistor 100 is an NMOS transistor, transition region 140 may be a medium doped n-type region. In some embodiments, transition region 140 and shield region 138 may be disposed at the same depth (for example the same depth along the x-axis illustrated in FIG. 1). Transition region 140 and shield region 138 may disposed in an alternating fashion in a striped transition-region pattern angularly offset from the striped gate pattern. For example, transition region 140 and shield region 138 may disposed in an alternating fashion in a striped transition-region pattern in a second direction of a second axis orthogonal to the first axis (for example, in a second direction of the y-axis orthogonal to the z-axis as shown in FIG. 1). As shown in FIG. 1, alternating stripes of transition region 140 and shield region 138 may extend length-wise in a direction of the y-axis for example, with widths of the stripes of transition region 140 and shield region 138 repeating in an alternating fashion in the direction of the z-axis. The striped transition-region pattern including transition region 140 and shield region 138 may be further seen in the cross-section views of FIGS. 2A, 2B, and 2C.

The orientation of the z-axis, y-axis, and x-axis is maintained consistently across each of the FIGS. 1, 2A-2D, and 3A-3D described herein. For the purposes of the present disclosure, and to aid the description and illustration of embodiments included herein, the z-axis may also be referred to as the first axis, the y-axis may also be referred to as the second axis, and the x-axis may also be referred to as the third axis. However, the designation of which axis is the “first,” which axis is the “second,” and which axis is the “third,” may be modified without departing from the scope of the present disclosure.

FIG. 2A illustrates a cross-section view of transistor 100 in accordance with embodiments of the present disclosure. Specifically, FIG. 2A illustrates a cross-section view of transistor 100 on an x-z plane following the x-axis and the z-axis shown in FIG. 1, and in particular along cutline 2A shown in FIG. 1. FIG. 2B illustrates a cross-section view of transistor 100 in accordance with embodiments of the present disclosure. Specifically, FIG. 2B illustrates a cross-section view of transistor 100 on an x-y plane following the x-axis and γ-axis shown in FIG. 1, and in particular along cutline 2B shown in FIG. 1.

As shown collectively in FIGS. 2A and 2B, shield region 138 and transition region 140 may be located between the current-spreading layer 130 and the super-junction region 150, which may include n-type pillar 152 and p-type pillar 154. In some embodiments, shield region 138 may have the same thickness (along the x-axis) and be located at the same depth as transition region 140. In some embodiments, transition region 140 may have a different doping level than current-spreading layer 130. For example, in embodiments where transistor 100 is an NMOS transistor, transition region 140 may have a lighter n-type doping than current-spreading layer 130. In other embodiments, transition region 140 may have the same doping concentration as current-spreading layer 130. In such embodiments, transition region 140 may be considered to be a portion of the current-spreading layer 130 that extends through shield region 138.

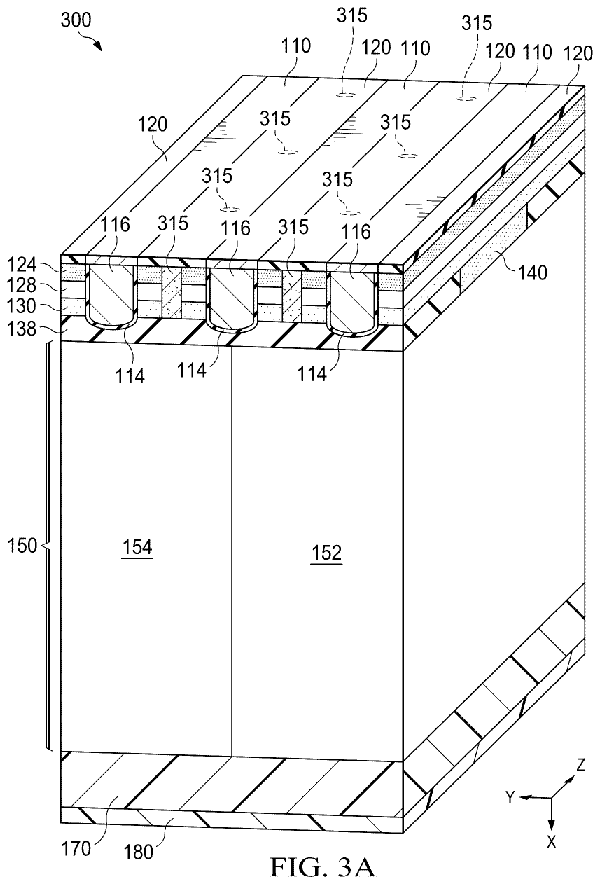

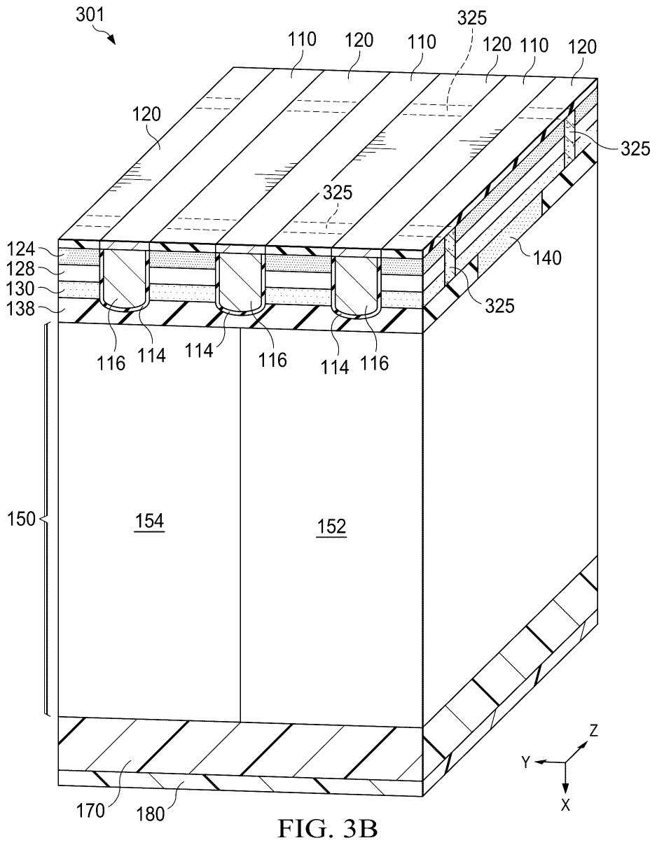

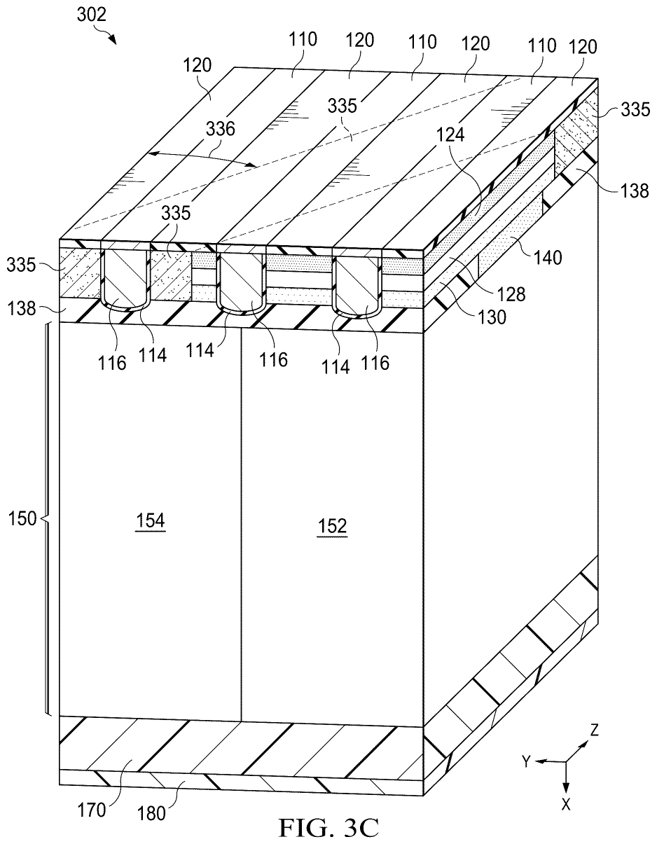

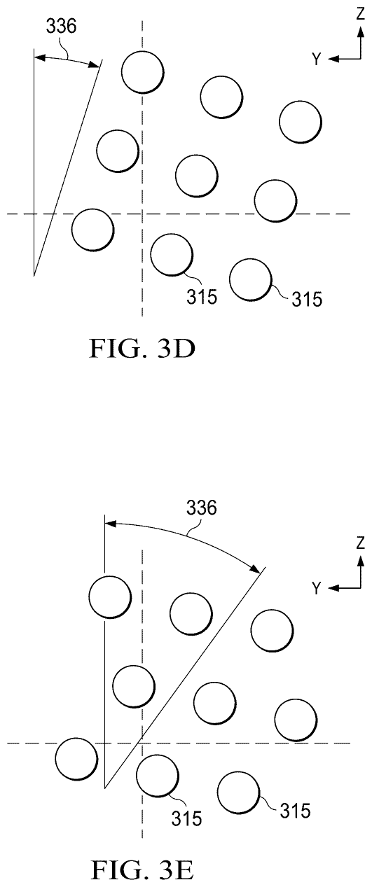

As described above, transition region 140 may funnel current travelling vertically through n-type pillar 152 to current-spreading layer 130 where current may then travel horizontally through current-spreading layer 130 toward the various channels formed in well region 128 by the application of a gate voltage to gate 116. Shield region 138, in combination with well region 128, may help provide a JFET-like effect for the current flowing through current-spreading layer 130. As described above, well region 128 and shield region 138 may be p-type regions. And as described below with reference to FIGS. 3A-3E, well region 128 and shield region 138 may be coupled to the source contact layer 120 to keep the p-type regions coupled to the source of transistor 100, and thus to the lowest voltage potential (for example ground) within transistor 100. Well region 128 and shield region 138 may thus form the gate of a depletion-mode junction field-effect transistor (JFET) pinching the current channel through current-spreading layer 130. Similarly, opposing portions of shield region 138 on opposite sides of transition region 140 may also form the gate of a depletion mode JFET pinching the current flow through transition region 140. The width of the channel through transition region 140 may however be larger than the width of the channel through current-spreading layer 130, and thus the JFET effect within transistor 100 may be predominated by the JFET-like structure formed by well region 128 and shield region 138 above and below current-spreading layer 130.

The JFET effect provided by well region 128 and shield region 138 above and below current-spreading layer 130 may help improve the short-circuit withstand time (SCWT) of transistor 100. For example, the JFET effect may provide for a flatter saturation current of transistor 100 across a range of large drain-to-source voltages, which may in turn limit the drain-to-source current of transistor 100 in a short-circuit condition. In such a short-circuit condition, the power system in which transistor 100 is implemented may incur a fault whereby transistor 100 is turned on by a gate voltage above the gate-to-source threshold of transistor 100 at the same time as a full system supply voltage is applied across the drain-to-source of transistor 100. During such conditions, the JFET effect may limit the current through transistor 100, thus extending the short-circuit withstand time (SCWT) during which transistor 100 may withstand the faulty short-circuit condition without failing. The saturation current for a given embodiment of transistor 100 may depend in part on the length of the JFET channel through current-spreading layer 130, the dimensions of which are described in further detail below with reference to FIG. 2C.

FIG. 2C illustrates a top cross-section view of transistor 100 in accordance with embodiments of the present disclosure. Specifically, FIG. 2C illustrates a cross-section view of transistor 100 on a y-z plane following the y-axis and the z-axis shown in FIG. 1, and particularly at a depth along the x-axis that intersect shield region 138 and transition region 140.

As shown in FIG. 2C, transition region 140 and shield region 138 may be disposed in an alternating fashion in a striped transition-region pattern angularly offset from the striped gate pattern. For example, transition region 140 and shield region 138 may be disposed in an alternating fashion in a striped transition-region pattern in a second direction of a second axis orthogonal to the first axis (for example in a second direction of the y-axis orthogonal to the first direction of the z-axis as shown in FIG. 2C). That is, the stripes may run in the direction of the y-axis and repeat in an alternating fashion along the z-axis. Although a single stripe of transition region 140 is illustrated in FIG. 2C, further stripes of transition region 140 may be repeated in an alternating fashion with stripes of shield region 138. The length of the JFET channel through current-spreading layer 130 along the z-axis described above with reference to FIGS. 2A and 2B may depend on the width of shield region 138 along the z-axis. The width of a stripe of shield region 138 along the z-axis may be equal to the transition-region pitch 141 (at which the alternating stripes of shield region 138 and transition region 140 repeat along the z-axis) minus the width of the transition region 140. Thus, the length of the JFET channel through current-spreading layer 130 may also be referred to as depending on the transition-region pitch 141 and the width of transition region 140 along the z-axis.

As collectively shown in FIGS. 1 and 2A-2C, transition region 140 and shield region 138 may disposed in an alternating fashion in a striped transition-region pattern angularly offset from the striped gate pattern. For example, transition region 140 and shield region 138 may be disposed in an alternating fashion in a striped transition-region pattern in a second direction of a second axis orthogonal to the first axis (for example, in a second direction of the y-axis orthogonal to the z-axis). By patterning transition region 140 and the shield region 138 in a striped transition-region pattern along a second axis (for example the y-axis) orthogonal to or otherwise angularly offset from the first axis (for example the z-axis) along which the striped gate pattern extends, the widths and pitch of transition region 140 and shield region 138 may be determined separately from the gate pitch 117 of the striped gate pattern. Thus, in some embodiments, the gate pitch 117 of the striped gate patten may be different than the transition-region pitch 141 of the striped transition-region pattern. The widths of shield region 138 and transition region 140, as well as the transition-region pitch 141, may therefore be selected based on a target saturation current value, without being limited to the same gate pitch 117 of the striped gate pattern.

Referring back to FIG. 1, transistor 100 may include super-junction region 150 located under shield region 138 and transition region 140. Super-junction region 150 may include n-type pillar 152 and p-type pillar 154. N-type pillar 152 and p-type pillar 154 may be disposed in an alternating fashion in a striped super-junction pattern angularly offset from the striped transition region pattern. For example, n-type pillar 152 and p-type pillar 154 may be disposed in an alternating fashion in a striped super-junction pattern in the first direction of the first axis orthogonal to the second axis (in the first direction of the z-axis orthogonal to the y-axis shown in FIG. 1). The striped super-junction pattern including n-type pillar 152 and p-type pillar 154 may be further seen in the top cross-section views of FIG. 2D. FIG. 2D illustrates a top cross-section view of transistor 100 in accordance with embodiments of the present disclosure. Specifically, FIG. 2D illustrates a top cross-section view of transistor 100 on a y-z plane following the y-axis and the z-axis shown in FIG. 1, and particularly at a depth along the x-axis that intersects n-type pillar 152 and p-type pillar 154. As collectively shown in FIG. 1 and FIG. 2D, alternating stripes of n-type pillar 152 and p-type pillar 154 may extend length-wise in a direction of the z-axis, with widths of the stripes of n-type pillar 152 and p-type pillar 154 repeating in an alternating fashion in the direction of the y-axis. Super-junction pitch 151 may define the width of the striped pattern including an instance of n-type pillar 152 and p-type pillar 154. Although a single instance of n-type pillar 152 and p-type pillar 154 is illustrated in FIGS. 1 and 2D, it is to be understood that further instances of super-junction region 150 may be repeated along the y-axis with alternating stripes of n-type pillar 152 and p-type pillar 154 in further areas of the semiconductor die not shown.

Super-junction region 150 may be configured to improve the breakdown voltage (BV) of transistor 100. For example, n-type pillar 152 and p-type pillar 154 may be charge balanced. As shown in FIG. 1, n-type pillar 152 and p-type pillar 154 may in some embodiments have the same width as each other. In such embodiments, the n-type doping concentration of n-type pillar 152 may be equal to the p-type doping concentration of p-type pillar 154 to maintain charge balance. In other embodiments, n-type pillar 152 may have a smaller or larger width along the y-axis than p-type pillar 154, and may thus have a proportionally larger or smaller doping concentration than p-type pillar 154 to maintain the charge balance of super-junction region 150 as a whole. The charge balance of p-type pillar 154 and n-type pillar 152 may allow super-junction region 150 to provide a higher blocking voltage, and thus a higher breakdown voltage (BV), as compared to a fully n-type drift layer.

As described above, during operation of transistor 100 in an on-state, current may flow from drain contact layer 180, through epitaxial region 170, through n-type pillar 152 of super-junction region 150, through transition region 140, and through current-spreading layer 130, from where current may then flow to the source region 124 through the various channels opened in well region 128 by the application of a sufficient gate voltage to gate 116. Higher n-type doping of n-type pillar 152 may provide for a lower resistance through n-type pillar 152, thus contributing to a lower on-resistance (RON) of transistor 100. However, higher n-type doping of n-type pillar 152 may also increase the total charge within n-type pillar 152, thus reducing the breakdown voltage (BV) of transistor 100. Another factor affecting the total charge within n-type pillar 152 is the width of n-type pillar 152 and the super-junction pitch 151 of the striped super-junction pattern. For example, reducing the super-junction pitch 151, and specifically the width of n-type pillar 152, may reduce the total charge in a single stripe of n-type pillar 152, thus providing a higher breakdown voltage (BV) for transistor 100 as a whole.

As shown collectively in FIGS. 1 and 2D, n-type pillar 152 and p-type pillar 154 may be disposed in an alternating fashion in a striped super-junction pattern angularly offset from the striped transition-region pattern. For example, n-type pillar 152 and p-type pillar 154 may be disposed in an alternating fashion in a striped super-junction pattern in the first direction of the first axis orthogonal to the second axis (for example in the first direction of the z-axis orthogonal to the y-axis as shown in FIG. 1). By patterning n-type pillar 152 and p-type pillar 154 in a striped super-junction pattern along the first axis (for example the z-axis) orthogonal to or otherwise angularly offset from the second axis (for example the y-axis) along which the striped transition-region pattern extends, the widths and pitch of n-type pillar 152 and p-type pillar 154 may be determined separately from the transition-region pitch 141 of the striped transition-region pattern including shield region 138 and transition region 140. Thus, in some embodiments, the transition-region pitch 141 of the striped transition-region pattern may be different than a super-junction pitch 151 of the striped super-junction pattern. Further, the gate pitch 117 of the striped gate pattern may be different than the super-junction pitch 151 of the striped super-junction pattern. The widths of n-type pillar 152 and p-type pillar 154, as well as the super-junction pitch 151, may therefore be selected based on target on-resistance (RON) and breakdown voltage (BV) values, without being limited to the same gate pitch 117 of the striped gate pattern or to the same transition-region pitch 141 of the striped transition-region pattern.

Referring again to FIG. 1, transistor 100 may include an epitaxial region 170 located under super-junction region 150. In some embodiments, epitaxial region 170 may have the first conductivity type. For example, in embodiments where transistor 100 is an NMOS transistor, epitaxial region 170 may be an n-doped region. Transistor 100 may also include a drain contact layer 180 abutting epitaxial region 170. Drain contact layer 180 may include, for example, a silicide that may improve the electrical conductivity of the contact between epitaxial region 170 and further metal layers (not shown in FIG. 1) added to the bottom of the semiconductor substrate and coupled to the drain terminal of transistor 100. As described above, during operation of transistor 100 in an on-state, current may flow from drain contact layer 180, through epitaxial region 170, through the n-type pillar 152 of super-junction region 150, through transition region 140, and through current-spreading layer 130, from where current may then flow to the source region 124 through the various channels opened in well region 128 by the application of a sufficient gate voltage to gate 116.

FIG. 3A illustrates a perspective view of transistor 300 in accordance with embodiments of the present disclosure. Transistor 300 may represent an embodiment of transistor 100 described above with reference to FIGS. 1 and 2A-2D. Transistor 300 may include certain elements similar to those of transistor 100, which may be arranged and may operate in a similar manner as described above with reference to transistor 100. For example, similar to transistor 100, transistor 300 may include interlayer dielectric 110, gate oxide 114, gate 116, source contact layer 120, source region 124, well region 128, current-spreading layer 130, shield region 138, transition region 140, super-junction region 150 including n-type pillar 152 and p-type pillar 154, epitaxial region 170, and drain contact layer 180.

Transistor 300 may also include a plurality of link regions 315. The plurality of link regions 315 may have the second conductivity type. For example, in embodiments where transistor 300 is an NMOS transistor, each of the plurality link regions 315 may be p-type doped regions, similar to well region 128 and shield region 138. As shown in FIG. 3A, the plurality of link regions 315 may extend in the direction of the x-axis from source contact layer 120 through source region 124, well region 128, and the current-spreading layer 130, to shield region 138. Each of the plurality of link regions 315 may couple well region 128 and shield region 138 to the source contact layer 120 to keep the p-type well region 128 and shield region 138 coupled to the source of transistor 300, and thus to the lowest voltage potential (for example ground) within transistor 300.

In some embodiments, a plurality of link regions 315 may each be formed in an island pattern. For example, as shown in FIG. 3A, each link region 315 may be surrounded by areas of source region 124, well region 128, and current-spreading layer 130. In some embodiments, such as shown in FIG. 3A, each link region 315 may have a circular shape relative to the z-y plane of the z-axis and the y-axis. In other embodiments, each link region 315 may have an oval shape, a square shape, a rectangular shape, or any other shape suitable to form a repeating island pattern relative to the z-y plane of the z-axis and the y-axis.

In some embodiments, the plurality of link regions 315 may be disposed in rows and in columns along the z-axis and the y-axis. For example, a plurality of link regions 315 may be disposed along an axis parallel to a first axis (for example along an axis parallel to the z-axis shown in FIG. 3A). Further, a plurality of link regions 315 may also be disposed along an axis orthogonal to the first axis (for example along an axis orthogonal to the z-axis and parallel to the y-axis shown in FIG. 3A). For example, a plurality of link regions 315 may be disposed along an axis parallel to the second axis (for example along an axis parallel to the y-axis) and centered about the width of a stripe of shield region 138.

In some embodiments, each link region 315 may be disposed at a distance (for example, 40 μm, 20 μm, 10 μm, 5 μm, or less) from another instance of link region 315 to maintain a sufficiently strong coupling of source contact layer 120 to each area of well region 128 and to each area of shield region 138. The spacing of link regions 315 along the y-axis may ensure for example that at least one instance of link region 315 couples to each respective area of well region 128 between respective gates 116. The spacing of link regions 315 along the z-axis may also ensure for example that at least one instance of link region 315 couples to each instance of shield region 138 between respective instances of transition region 140.

FIG. 3B illustrates a perspective view of transistor 301 in accordance with embodiments of the present disclosure. Transistor 301 may represent an alternative embodiment of transistor 300 described above with reference to FIG. 3A. Transistor 301 may include certain elements similar to those of transistor 100 and transistor 300, which may be arranged and may operate in a similar manner as described above with reference to transistor 100 and transistor 300. For example, similar to transistor 100 and transistor 300, transistor 301 may include interlayer dielectric 110, gate oxide 114, gate 116, source contact layer 120, source region 124, well region 128, current-spreading layer 130, shield region 138, transition region 140, super-junction region 150 including n-type pillar 152 and p-type pillar 154, epitaxial region 170, and drain contact layer 180.

Transistor 301 may also include a plurality of link regions 325. The plurality of link regions 325 may have the second conductivity type. For example, in embodiments where transistor 301 is an NMOS transistor, each of the plurality link regions 325 may be p-type doped regions, similar to well region 128 and shield region 138. As shown in FIG. 3B, the plurality of link regions 325 may extend in the direction of the x-axis from source contact layer 120 through source region 124, well region 128, and the current-spreading layer 130, to shield region 138. Each of the plurality of link regions 325 may couple well region 128 and shield region 138 to the source contact layer 120 to keep the p-type well region 128 and shield region 138 coupled to the source of transistor 301, and thus to the lowest voltage potential (for example ground) within transistor 301.

In some embodiments, a plurality of link regions 325 may each be formed in an striped pattern. For example, as shown in FIG. 3B, a plurality of link regions 325 may be disposed along an axis parallel to the second axis (for example along an axis parallel to the y-axis) and centered about the width of a stripe of shield region 138. As another example, the plurality of link regions 325 may be disposed in striped pattern with stripes running length-wise parallel to the second axis (for example along an axis parallel to the y-axis).

In some embodiments, each link region 325 may be disposed at a distance (for example, 40 μm, 20 μm, 10 μm, 5 μm, or less) from another instance of link region 325 to maintain a sufficiently strong coupling of source contact layer 120 to each area of well region 128 and to each area of shield region 138. At least one instance of link region 325 may be coupled to each respective area of well region 128 between respective gates 116. Further, the spacing of link regions 325 along the z-axis may also ensure for example that at least one instance of link region 325 couples to each instance of shield region 138 between respective instances of transition region 140.

FIG. 3C illustrates a perspective view of transistor 302 in accordance with embodiments of the present disclosure. Transistor 302 may represent an alternative embodiment of transistor 300 described above with reference to FIG. 3A. Transistor 302 may include certain elements similar to those of transistor 100 and transistor 300, which may be arranged and may operate in a similar manner as described above with reference to transistor 100 and transistor 300. For example, similar to transistor 100 and transistor 300, transistor 302 may include interlayer dielectric 110, gate oxide 114, gate 116, source contact layer 120, source region 124, well region 128, current-spreading layer 130, shield region 138, transition region 140, super-junction region 150 including n-type pillar 152 and p-type pillar 154, epitaxial region 170, and drain contact layer 180.

Transistor 302 may also include a plurality of link regions 335. The plurality of link regions 335 may have the second conductivity type. For example, in embodiments where transistor 302 is an NMOS transistor, each of the plurality link regions 335 may be p-type doped regions, similar to well region 128 and shield region 138. As shown in FIG. 3C, the plurality of link regions 335 may extend in the direction of the x-axis from source contact layer 120 through source region 124, well region 128, and the current-spreading layer 130, to shield region 138. Each of the plurality of link regions 335 may couple well region 128 and shield region 138 to the source contact layer 120 to keep the p-type well region 128 and shield region 138 coupled to the source of transistor 302, and thus to the lowest voltage potential (for example ground) within transistor 302.

As shown in FIG. 3C, a plurality of link regions 335 may each be formed in an striped pattern. For example, the plurality of link regions 335 may be disposed in striped pattern with stripes running length-wise at an angle 336 from the first axis (at an angle 336 from the z-axis). In some embodiments, each link region 335 may be disposed in a linear pattern angularly offset from the striped gate pattern at an angle within a range from 20 degrees to 70 degrees.

In some embodiments, each linear pattern of link region 335 may be disposed at a distance (for example, 40 μm, 20 μm, 10 μm, 5 μm, or less) from another instance of link region 335 to maintain a sufficiently strong coupling of source contact layer 120 to each area of well region 128 and to each area of shield region 138. At least one instance of link region 335 may be coupled to each respective area of well region 128 between respective gates 116. Further, the spacing of link regions 335 along the z-axis may also ensure for example that at least one instance of link region 335 couples to each instance of shield region 138 between respective instances of transition region 140.

By intersecting the gate structures formed by gate oxide 114 and gate 116, link regions 335 may sacrifice a portion of the channel formed in well region 128. However, an increase in on-resistance (RON) due to sacrificing a portion of the channel may be offset by the greater impact removing the constraint of maintaining a minimum spacing between the link region and the gate structure to prevent gate misalignment. Accordingly, the trenches in which gate oxide 114 and gate 116 are formed may be disposed in the semiconductor substrate with a smaller gate pitch, thereby increasing the number of fingers of the transistor and reducing on-resistance (RON) for a given semiconductor die area.

FIGS. 3D and 3E illustrate top views of link implant patterns in accordance with embodiments of the present disclosure. As described above with reference to FIG. 3A, link regions 315 may be disposed in an island pattern with rows disposed along an axis parallel to the z-axis and columns disposed along an axis parallel to the y-axis. In some embodiments, the rows and columns may be offset from the z-axis and the y-axis at an angle. For example, as shown in FIG. 3D, the rows of link region 315 may be disposed along an axis that is offset from the z-axis by an angle 336. In some embodiments, angle 336 may be for example in a range from 20 degrees to 70 degrees. In other embodiments, a plurality of link regions 315 may be disposed for example in a hexagonal pattern as shown in FIG. 3D. In either such embodiment as shown in FIG. 3D and FIG. 3E, each link region 315 may be disposed at a distance (for example, 40 μm, 20 μm, 10 μm, 5 μm, or less) from another instance of link region 315 to maintain a sufficiently strong coupling of source contact layer 120 to each area of well region 128 and to each area of shield region 138. The spacing of link regions 315 along the y-z plane may ensure for example that at least one instance of link region 315 couples to each respective area of well region 128 between respective gates 116, and may also ensure that at least one instance of link region 315 couples to each instance of shield region 138 between respective instances of transition region 140.

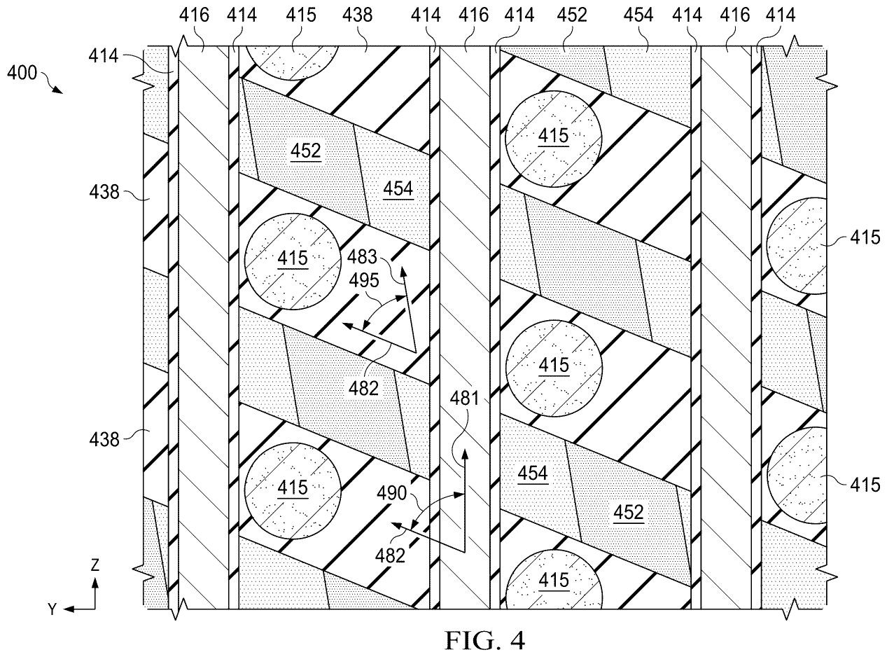

FIG. 4 illustrates a top layout view of transistor 400 in accordance with embodiments of the present disclosure. Transistor 400 may include certain elements similar to those of transistor 100 and transistor 300, which may be layered and may operate in a similar manner as described above with reference to transistor 100 (FIG. 1) and transistor 300 (FIG. 3). For example, similar to transistor 100 and transistor 300, transistor 400 may include an interlayer dielectric, a gate oxide, a gate, a source contact layer, a source region, a well region, a current-spreading layer, a shield region, a transition region, a super-junction region including an n-type pillar and a p-type pillar, an epitaxial region, and a drain contact layer. The top layout view shown in FIG. 4 however includes only certain layers so as to illustrate the respective angular relationships of the striped gate pattern of the gate, the striped transition-region pattern of the shield region and the transition region, and the striped super-junction pattern of the n-type pillar and the p-type pillar. For example, FIG. 4 illustrates from a top layout view gate oxide 414, gate 416, link region 415, shield region 438, n-type pillar 452, and p-type pillar 454, but omits from view the included interlayer dielectric, source contact layer, source region, well region, current-spreading layer, and transition region (as well as the epitaxial region and the drain contact layer) such that the respective patterns of gate 416, shield region 438, n-type pillar 452, and p-type pillar 454 may be viewed in relation to each other.

As shown in FIG. 4, gate 416 of transistor 400 may be disposed in striped gate pattern. For example, gate 416 of transistor may be disposed in a striped gate pattern in a first direction 481 parallel to the z-axis. Although the transition region is omitted from view in FIG. 4 to show underlying layers, shield region 438 may be disposed in an alternating fashion with a transition region in a striped transition-region pattern angularly offset from the striped gate pattern. For example, shield region 438 may be disposed in an alternating fashion with a transition region in a striped transition-region pattern in a second direction 482 that is offset by an angle 490 from the first direction 481 of the striped gate pattern. By forming the striped transition-region pattern along a second direction 482 angularly offset from the first direction 481 of the striped gate pattern, the widths and pitch of the transition region and shield region may be determined separately from the gate pitch of the striped gate pattern. Thus, in some embodiments, the gate pitch of the striped gate patten may be different than the transition-region pitch of the striped transition-region pattern. The widths of shield region and transition region, as well as the transition-region pitch, may therefore be selected based on a target saturation current value, without being limited to the same gate pitch of the striped gate pattern.

As also shown in FIG. 4, n-type pillar 452 and p-type pillar 454 may be disposed in an alternating fashion in a striped super-junction pattern angularly offset from the striped transition-region pattern. For example, n-type pillar 452 and p-type pillar 454 may be disposed in an alternating fashion in a striped super-junction pattern in a third direction 483 that is offset by an angle 495 from the second direction 482 of the of the striped transition-region pattern. By patterning n-type pillar 452 and p-type pillar 454 in a striped super-junction pattern in a third direction 483 angularly offset from the second direction 482 of the striped transition-region pattern, the widths and pitch of n-type pillar 452 and p-type pillar 454 may be determined separately from the transition-region pitch of the striped transition-region pattern. Thus, in some embodiments, the transition-region pitch of the striped transition-region pattern may be different than a super-junction pitch of the striped super-junction pattern. Further, the gate pitch of the striped gate pattern may be different than the super-junction pitch of the striped super-junction pattern. The widths of n-type pillar 452 and p-type pillar 454, as well as the super-junction pitch, may therefore be selected based on target on-resistance (RON) and breakdown voltage (BV) values, without being limited to the same gate pitch of the striped gate pattern or to the same transition-region pitch of the striped transition-region pattern.

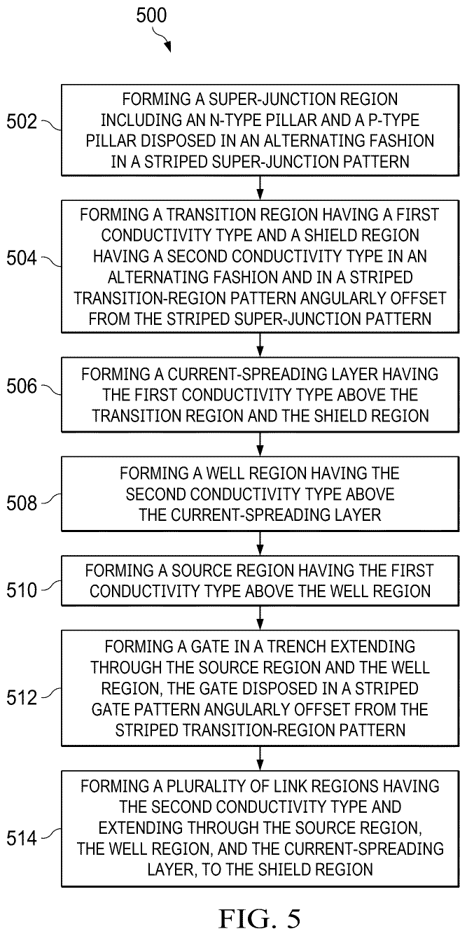

FIG. 5 illustrates method 500 for manufacturing a super-junction transistor in accordance with embodiments of the present disclosure. Method 500 may be performed by any suitable mechanism. Method 500 may be performed with fewer or more steps than shown in FIG. 5.

Moreover, steps of method 500 may be omitted, repeated, performed in parallel, performed in a different order than shown in FIG. 5, or performed recursively. One or more steps of method 500, although shown in an order, may be performed at the same time or in a re-ordered manner. For example, although the steps illustrated in FIG. 5 generally address the formation of layers in a direction from the bottom of the semiconductor substrate toward the upper surface of the semiconductor substrate, different doping implants at different depths may be utilized in any suitable order to form the regions described herein.

Step 502 may include forming a super-junction region including an n-type pillar and a p-type pillar disposed in an alternating fashion in a striped super-junction pattern. For example, as described above with reference to FIG. 1 and FIG. 2D, super-junction region 150 may be formed in the semiconductor substrate and may include n-type pillar 152 and p-type pillar disposed in an alternating fashion in a striped super-junction pattern in a first direction of a first axis orthogonal to the second axis (in the first direction of the z-axis orthogonal to the y-axis shown in FIG. 1). Though described herein as being formed as part of super-junction region 150, n-type pillar 152 and p-type pillar 154 may be formed by different doping routines. For example, n-type pillar 152 may be formed in the semiconductor substrate by applying a patterned n-type doping implant at a depth extending above epitaxial region 170, as illustrated in FIG. 1 for example. Similarly, p-type pillar 154 may be formed in the semiconductor substrate by applying a patterned p-type doping implant at a depth extending above epitaxial region 170. As collectively shown in FIG. 1 and FIG. 2D, alternating stripes of n-type pillar 152 and p-type pillar 154 may be patterned to extend length-wise in a direction of the z-axis, with widths of the stripes of n-type pillar 152 and p-type pillar 154 repeating in an alternating fashion in the direction of the y-axis.

Step 504 may include forming a transition region having a first conductivity type and a shield region having a second conductivity type in an alternating fashion and in a striped transition-region pattern angularly offset from the striped super-junction pattern. For example, a transition region having a first conductivity type and a shield region having a second conductivity type may be formed in an alternating fashion and in a striped transition-region pattern in a second direction of a second axis orthogonal to or otherwise angularly offset from the first axis. As described above with reference to FIG. 1 and FIGS. 2A-2C, transition region 140 and shield region 138 may be formed in the semiconductor substrate above super-junction region 150. Transition region 140 be an n-type region while shield region 138 may be a p-type region. Transition region 140 may be formed in the semiconductor substrate by applying a patterned n-type doping implant at a depth extending above super-junction region 150, as illustrated in FIGS. 1 and 2A-2C. Similarly, shield region 138 may be formed in the semiconductor substrate by applying a patterned p-type doping implant also at a depth extending above super-junction region 150. As collectively shown in FIGS. 1 and 2A-2C, alternating stripes of transition region 140 and shield region 138 may be patterned to extend length-wise in the direction of the y-axis and orthogonal to the z-axis for example. The striped pattern of transition region 140 and shield region 138 may repeat in an alternating fashion in the direction of the z-axis.

Step 506 may include forming a current-spreading layer having the first conductivity type above the transition region and the shield region. For example, as described above with reference to FIG. 1, current-spreading layer 130 may be formed above transition region 140 and shield region 138. Current-spreading layer 130 may be an n-type region. Current-spreading layer 130 may be formed in the semiconductor substrate by applying an n-type doping implant at a depth extending above transition region 140 and shield region 138, as illustrated in FIGS. 1 and 2A-2B.

Step 508 may include forming a well region having the second conductivity type above the current-spreading layer. For example, as described above with reference to FIG. 1, well region 128 may be formed in the semiconductor substrate above current-spreading layer 130. Well region 128 may be a p-type region. For example, well region 128 may be formed in the semiconductor substrate by applying a p-type doping implant at a depth extending above current-spreading layer 130, as illustrated in FIGS. 1 and 2A-2B.

Step 510 may include forming a source region having the first conductivity type above the well region. For example, as described above with reference to FIG. 1, source region 124 may be formed in the semiconductor substrate above well region 128. Source region 124 may be a heavily doped n-type region. For example, source region 124 may be formed in the semiconductor substrate by applying a heavy n-type doping implant at a depth extending above well region 128, as illustrated in FIGS. 1 and 2A-2B.

Step 512 may include forming a gate in a trench extending through the source region and the well region, the gate disposed in a striped gate pattern angularly offset from the striped transition-region pattern. For example, the gate may be disposed in a striped gate pattern in the first direction of the first axis orthogonal to the second axis. As described above with reference to FIG. 1, a trench may be formed by an etch pattern at the upper surface of the semiconductor substrate. After the etch, gate oxide 114 may be grown or deposited along the sidewalls and bottom of the trench. Gate oxide 114 may include silicon dioxide, for example, or any other oxide suitable to form a gate dielectric. Gate 116 may subsequently be deposited to fill remaining area of the trench. In some embodiments, gate 116 may be formed by a heavily doped polysilicon, for example. As shown in FIG. 1, gate 116 may be disposed in a striped gate pattern in a first direction of a first axis (for example the z-axis) orthogonal to or otherwise angularly offset from the second axis (for example the y-axis). Specifically, stripes of gate 116 may extend length-wise in a direction of the z-axis, with the stripes repeating at a gate pitch 117 along the y-axis.

Step 514 may include forming a plurality of link regions having the second conductivity type and extending through the source region, the well region, and the current-spreading layer, to the shield region. For example, as described above with reference to FIGS. 3A-3C, a plurality of link regions, such as link regions 315 (FIG. 3A), link regions 325 (FIG. 3B), or link regions 335 (FIG. 3C), may be formed in the semiconductor substrate extending from source contact layer 120, through source region 124, well region 128, and current-spreading layer 130 to shield region 138. The link regions, such as link regions 315 (FIG. 3A), link regions 325 (FIG. 3B), or link regions 335 (FIG. 3C), may be p-type regions. For example, link regions such as link regions 315 (FIG. 3A), link regions 325 (FIG. 3B), or link regions 335 (FIG. 3C), may be formed in the semiconductor substrate by applying a p-type doping implant at a depth extending through source region 124, well region 128, and current-spreading layer 130, to shield region 138. Each of the plurality of link regions may be coupled well region 128 and shield region 138 to source contact layer 120 to keep the p-type well region 128 and shield region 138 coupled to the source of transistor the transistor, and thus to the lowest voltage potential (for example ground) within the transistor.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A transistor, comprising:
a source region having a first conductivity type;
a well region located under the source region and having a second conductivity type;
a current-spreading layer located under the well region and having the first conductivity type;
a gate formed in a trench extending through the source region and the well region, the gate disposed in a striped gate pattern;
a transition region located under the current-spreading layer and having the first conductivity type;
a shield region located under the current-spreading layer and having the second conductivity type, wherein the transition region and the shield region are disposed in an alternating fashion in a striped transition-region pattern angularly offset from the striped gate pattern; and
a super-junction region located under the shield region and the transition region, the super-junction region including an n-type pillar and a p-type pillar disposed in an alternating fashion in a striped super-junction pattern angularly offset from the striped transition-region pattern.

2. The transistor of claim 1, wherein:
the gate is disposed in the striped gate pattern in a first direction of a first axis; and
the transition region and the shield region are disposed in an alternating fashion in the striped transition-region pattern in a second direction of a second axis orthogonal to the first axis.

3. The transistor of claim 1, wherein:
the n-type pillar and the p-type pillar are disposed in an alternating fashion in the striped super-junction pattern in a first direction of a first axis; and
the transition region and the shield region are disposed in an alternating fashion in the striped transition-region pattern in a second direction of a second axis orthogonal to the first axis.

4. The transistor of claim 1, wherein a gate pitch of the striped gate pattern is different than a transition-region pitch of the striped transition-region pattern.

5. The transistor of claim 1, wherein a gate pitch of the striped gate pattern is different than a super-junction pitch of the striped super-junction pattern.

6. The transistor of claim 1, wherein a transition-region pitch of the striped transition-region pattern is different than a super-junction pitch of the striped super-junction pattern.

7. The transistor of claim 1, further comprising:
a source contact layer located above the source region; and
a plurality of link regions having the second conductivity type and extending from the source contact layer through the source region, the well region, and the current-spreading layer, to the shield region.

8. The transistor of claim 7, wherein each link region is disposed in a linear pattern angularly offset from the striped gate pattern at an angle within a range from 20 degrees to 70 degrees.

9. The transistor of claim 7, wherein:
the gate is disposed in the striped gate pattern in a first direction of a first axis; and
the plurality of link regions are disposed in an island pattern along an axis parallel to the first axis.

10. The transistor of claim 7, wherein:
the gate is disposed in the striped gate pattern in a first direction of a first axis; and
the plurality of link regions are disposed in an island pattern along an axis orthogonal to the first axis.

11. The transistor of claim 1, wherein the transistor is a silicon carbide transistor.

12. The transistor of claim 1, wherein the transistor is an NMOS transistor.

13. A super-junction transistor, comprising:
a source region having a first conductivity type;
a well region located under the source region and having a second conductivity type;
a current-spreading layer located under the well region and having the first conductivity type;
a gate formed in a trench extending through the source region and the well region, the gate disposed in a striped gate pattern in a first direction of a first axis;
a transition region located under the current-spreading layer and having the first conductivity type;
a shield region located under the current-spreading layer and having the second conductivity type, wherein the transition region and the shield region are disposed in an alternating fashion in a striped transition-region pattern in a second direction of a second axis orthogonal to the first axis; and
a super-junction region located under the shield region and the transition region, the super-junction region including an n-type pillar and a p-type pillar disposed in an alternating fashion in a striped super-junction pattern in the first direction of the first axis.

14. The super-junction transistor of claim 13, wherein:
a gate pitch of the striped gate pattern is different than a transition-region pitch of the striped transition-region pattern;
the gate pitch of the striped gate pattern is different than a super-junction pitch of the striped super-junction pattern; and
the transition-region pitch of the striped transition-region pattern is different than the super-junction pitch of the striped super-junction pattern.

15. The super-junction transistor of claim 13, wherein the super-junction transistor is a silicon carbide transistor.

16. A method comprising:
forming a super-junction region including an n-type pillar and a p-type pillar disposed in an alternating fashion in a striped super-junction pattern;
forming a transition region having a first conductivity type and a shield region having a second conductivity type in an alternating fashion and in a striped transition-region pattern angularly offset from the striped super-junction pattern;
forming a current-spreading layer having the first conductivity type above the transition region and the shield region;
forming a well region having the second conductivity type above the current-spreading layer;
forming a source region having the first conductivity type above the well region; and
forming a gate in a trench extending through the source region and the well region, the gate disposed in a striped gate pattern angularly offset from the striped transition-region pattern.

17. The method of claim 16, wherein:
the gate is disposed in the striped gate pattern in a first direction of a first axis; and
the transition region and the shield region are disposed in an alternating fashion in the striped transition-region pattern in a second direction of a second axis orthogonal to the first axis.

18. The method of claim 16, wherein:
the n-type pillar and the p-type pillar are disposed in an alternating fashion in the striped super-junction pattern in a first direction of a first axis; and
the transition region and the shield region are disposed in an alternating fashion in the striped transition-region pattern in a second direction of a second axis orthogonal to the first axis.

19. The method of claim 16, wherein transition-region pitch of the striped transition-region pattern is different than a gate pitch of the striped gate pattern and a super-junction pitch of the striped super-junction pattern.

20. The method of claim 16, further comprising forming a plurality of link regions having the second conductivity type and extending through the source region, the well region, and the current-spreading layer, to the shield region.
